(19) United States
(12) Patent Application Publication
(10) Pub. No.: US 2010/0123509 A1
(43) Pub. Date: May 20, 2010

(54) PAD CIRCUIT FOR THE PROGRAMMING AND I/O OPERATIONS

(76) Inventors: Wei-Yao Lin, Hsinchu County (TW); Shao-Chang Huang, Hsinchu City (TW); Wei-Ming Ku, Taipei County (TW); Tang-Lung Lee, Taipei County (TW); Kun-Wei Chang, Taipei County (TW); Shih-Hsien Wang, Kaohsiung City (TW); Yi-Ling Kuo, Yunlin County (TW); Mao-Shu Hsu, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 12/273,564

(22) Filed: Nov. 19, 2008

(51) Int. Cl. H03K 17/687

(52) U.S. Cl. 327/436

(57) ABSTRACT

A pad circuit includes a pad, a gate driving circuit, a voltage selection circuit, and an ESD detection/avoiding circuit. The gate driving circuit is used to discharge the ESD induced current. The ESD detection/avoiding circuit is used to isolate the ESD induced voltage. The voltage selection circuit selects a higher voltage from a power/ground terminal and the pad and outputs it to the gate driving circuit, so that the pad circuit can be used for the programming and 1/0 operations.

### BACKGROUND OF THE INVENTION

1. Field of the Invention

The present invention relates to a pad circuit, and more particularly, to a pad circuit for the programming and I/O operations.

2. Description of the Prior Art

A typical chip is equipped with conductive pads to receive external power potentials and to exchange data with other external circuits/chips. For example, the chip is equipped with power pads and ground pads to transmit the positive or negative voltage and the ground voltage to the power supplies. Similarly, the chip is also equipped with signal input/output (I/O) pads to receive input signals and to transmit output signals. The chip communicates with other circuit through the conductive pads. However, an integrated circuit (IC) chip may be subjected to an Electrostatic Discharge (ESD) event both in the manufacturing process and in the system application. The ESD signal may be transmitted into the chip through the pads of the chip, which damages the internal circuit of the chip. Thus, the pad circuit of the chip is designed for buffering signals as well as protecting ESD events.

Please refer to FIG. 1. FIG. 1 is a schematic diagram of a pad circuit 1 0 according to the prior art. The pad circuit 10 is used for the programming operation. In addition, the pad circuit 10 has an ESD protection circuit to discharge the ESD induced current. In the pad circuit 10, the resistor R and the capacitor C are coupled in series to the pad 11 and the power/ground terminal VSS to form a resistor-capacitor (RC) network. The PMOS transistor P1 and NMOS transistor N2 are coupled to the pad 11 and the power/ground terminal VSS as an inverter. The gates of the two transistors P1 and N2 as the input of the inverter are controlled by the voltage at the node A2 of the RC network while the drains of the two transistors P1 and N2 as the output of the inverter control the trigger of the NMOS transistor N1 at the node A1. When the NMOS transistor N1 between the pad 11 and the power/ground terminal VSS is triggered by a high voltage, the NMOS transistor N1 opens a conducting current path of low impendence between the pad 11 and the power/ground terminal VSS. Thus, the ESD induced current can be discharged.

When the pad circuit 10 is used for receiving voltage signals, the NMOS transistor N1 should be turned off to prevent the leakage current. For example, when the pad circuit 10 is used for the programming operation, a programming voltage 7.5V is applied to the pad 11. Thus, a high voltage level is generated at the node A2 and a low voltage level is generated at the node A1. The NMOS transistor N1 is turned off, and the transmission gate 16 is turned on. The programming voltage is transmitted to the node A4. Unfortunately, the pad circuit 10 cannot be used for the I/O operation. Referring to FIG. 1 again, when the pad 11 receives I/O voltages 0/3.3 Volts, the NMOS transistor N1 will induce a large leakage current at I/O transient states. For example, when the I/O voltage changes from 0 Volts to 3.3 Volts, the PMOS transistor P1 is turned on so as to generate a high voltage level at the node A1. Thus, the NMOS transistor N1 is turned on and the leakage current is generated.

### SUMMARY OF THE INVENTION

According to an embodiment of the present invention, a pad circuit for the programming and I/O operations comprises a pad, a gate driving circuit, a voltage selection circuit, and an ESD detection/avoiding circuit. The gate driving circuit is coupled between the pad and a first power/ground terminal, for discharging an ESD induced current. The voltage selection circuit is coupled to the pad and a second power/ground terminal, for outputting a voltage of the pad or a voltage of the second power/ground terminal to the gate driving circuit. The ESD detection/avoiding circuit is coupled to the pad, for isolating an ESD induced voltage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a pad circuit according to the prior art.

FIG. 2 is a schematic diagram of a first embodiment of a pad circuit according to the present invention.

FIG. 3 is a truth table for the voltage selection circuit.

FIG. 4A, FIG. 4B, and FIG. 4C are schematic diagrams of a second embodiment of a pad circuit according to the present invention.

FIG. 5 is a schematic diagram of a third embodiment of a pad circuit according to the present invention.

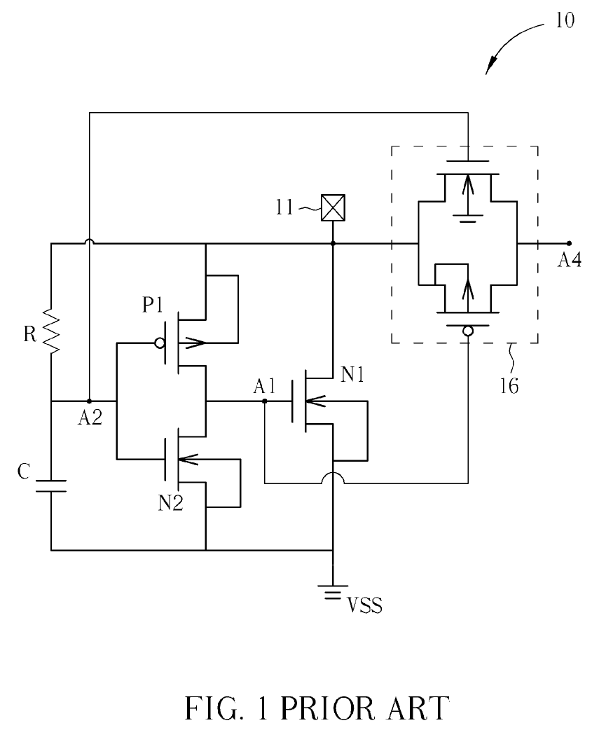

### DETAILED DESCRIPTION

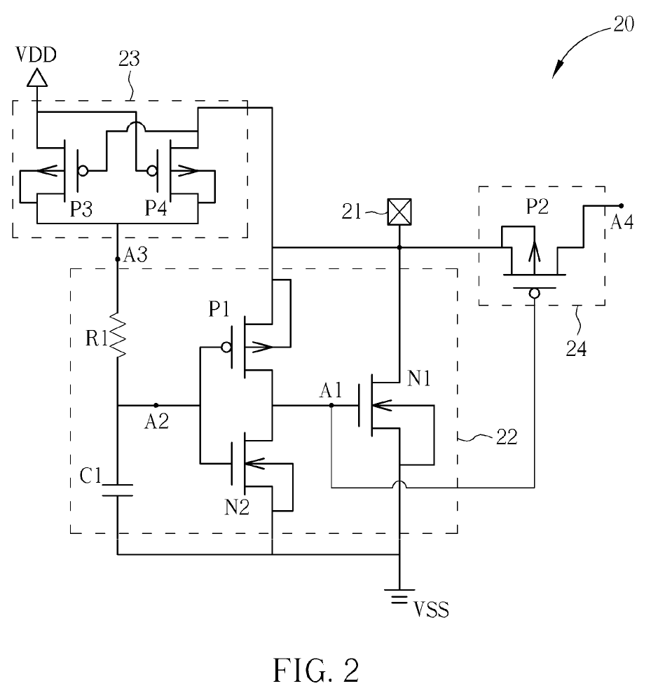

Please refer to FIG. 2. FIG. 2 is a schematic diagram of a first embodiment of a pad circuit 20 according to the present invention. The pad circuit 20 includes a pad 21, a gate driving circuit 22, a voltage selection circuit 23, and an ESD detection/avoiding circuit 24. The gate driving circuit 22 is used to discharge the electrostatic discharge (ESD) induced current. The gate driving circuit 22 includes an NMOS transistor N1, a PMOS transistor P1, an NMOS transistor N2, a resistor R1 and a capacitor C1. The gate of the NMOS transistor N1 is coupled to the node A1. The source of the NMOS transistor N1 is coupled to the first power/ground terminal VSS. The drain of the NMOS transistor N1 is coupled to the pad 21. The gate of the PMOS transistor P1 is coupled to the node A2. The source of the PMOS transistor P1 is coupled to the pad 21. The drain of the PMOS transistor P1 is coupled to the node A1. The gate of the NMOS transistor N2 is coupled to the node A2. The source of the NMOS transistor N2 is coupled to the first power/ground terminal VSS. The drain of the NMOS transistor N2 is coupled to the node A1. The first end of the resistor R1 is coupled to the node A3. The second end of the resistor R1 is coupled to node A2. The first end of the capacitor C1 is coupled to the node A2. The second end of the capacitor C1 is coupled to the first power/ground terminal VSS. The ESD detection/avoiding circuit 24 is used to isolate the ESD induced voltage. The ESD detection/avoiding circuit 24 includes a PMOS transistor P2. The gate of the PMOS transistor P2 is coupled to the node A1. The source of the PMOS transistor P2 is coupled to the pad 21. The drain of the PMOS transistor P2 is coupled to the node A4.

The voltage selection circuit 23 selects a high voltage from the second power/ground terminal and the pad 21 and outputs the selected voltage to the gate driving circuit 22, so that the pad circuit 20 can be used for the programming and I/O operations. The voltage selection circuit 23 includes a PMOS transistor P3 and a PMOS transistor P4. The source of the PMOS transistor P3 is coupled to the second power/ground terminal VDD. The gate of the PMOS transistor P3 is coupled to the pad 21. The drain and the body of the PMOS transistor P3 are coupled to the node A3. The source of the PMOS transistor P4 is coupled to the pad 21. The gate of the PMOS transistor P4 is coupled to the second power/ground terminal VDD. The drain and the body of the PMOS transistor P4 are coupled to the node A3. By switching the PMOS transistors P3 and P4, a higher voltage is selected from the voltage of the second power/ground terminal VDD and the voltage of the pad 21 to the node A3.

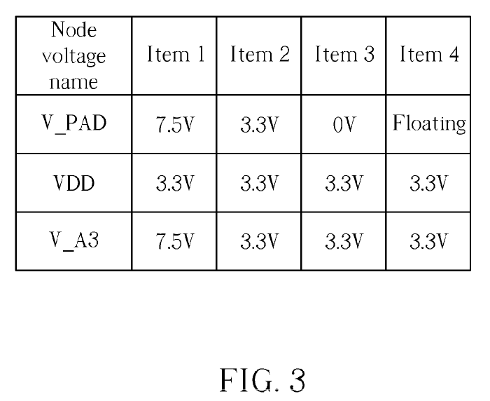

Please refer to FIG. 3. FIG. 3 is a truth table for the voltage selection circuit 23. V_PAD is the voltage of the pad 21. VDD is the power supply that provides 3.3V. V_A3 is the voltage of the node A3. When the pad circuit 20 is used for the programming operation, the pad 21 receives a programming voltage, for example, 7.5 Volts. Thus, the PMOS transistor P3 is turned off, and the PMOS transistor P4 is turned on. The voltage of the node A3 is 7.5V. The node A2 is at a high voltage level and the node A1 is at a low voltage level. Thus, the NMOS transistor N1 is turned off and the PMOS transistor P2 is turned on. The programming voltage is transmitted to the node A4. For the I/O operation, the pad 21 receives an I/O voltage, for example, 3.3 Volts or 0 Volt. The voltage selection circuit 23 can select the high voltage from the second power/ground terminal VDD and the pad 21. When the pad 21 receives the voltage 3.3 Volts or 0 Volt, the voltage of the node A3 is always 3.3 Volts. The node A2 is at the high voltage level and the node A1 is at the low voltage level. Thus, the NMOS transistor N1 is turned off and the PMOS transistor P2 is turned on. The I/O voltage is transmitted to the node A4. However, the I/O voltage can be transmitted from the pad 21 to an internal circuit directly.

In addition, the pad circuit 20 can protect the pad 21 from ESD events referenced to the first power/ground terminal VSS. In response to an ESD event that induces a rapid positive voltage increased on the pad 21, the capacitor C1 initially holds the node A2 well below the pad 21. The gate driving circuit 22 drives the gate of the NMOS transistor N1 to turn on the NMOS transistor N1. Once turned on, the NMOS transistor N1 acts as a low resistance between the pad 21 and the first power/ground terminal VSS. The NMOS transistor N1 will remain conductive for a period of time which is determined by the RC time constant of the gate driving circuit 22. As a result, this RC time constant should be set long enough to exceed the maximum expected duration of an ESD event.

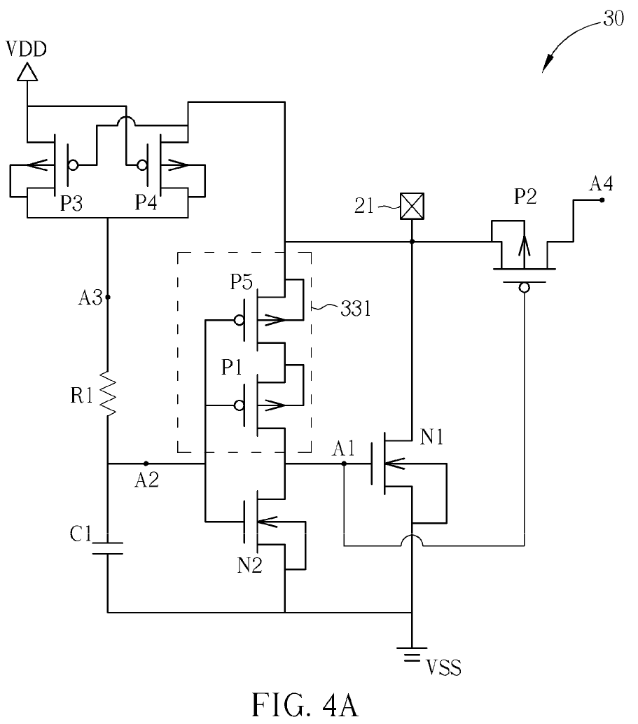

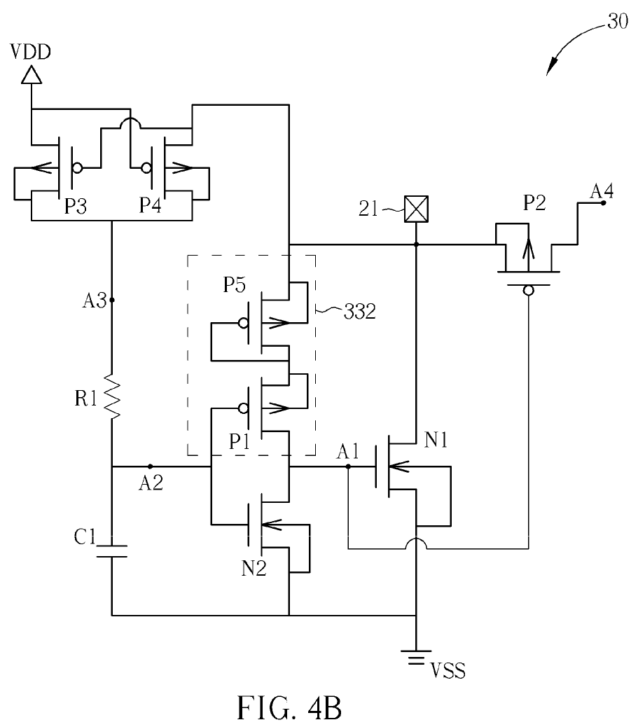

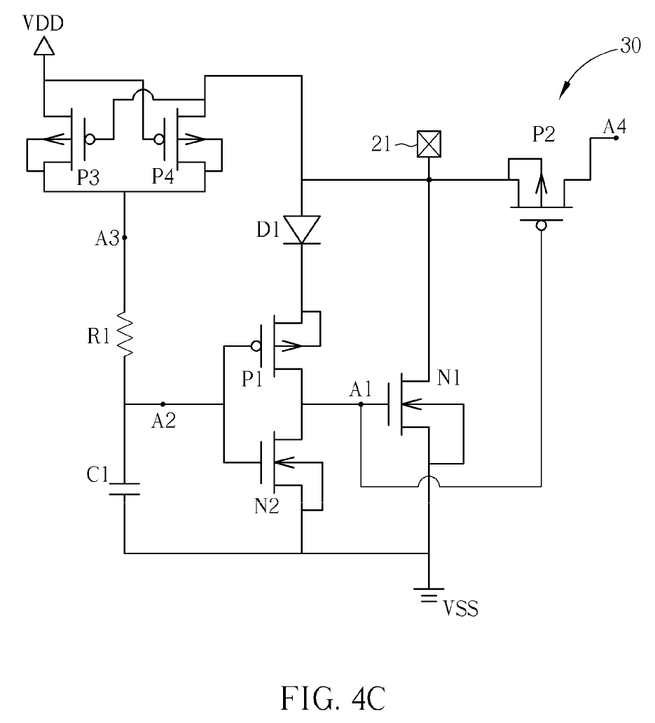

Please refer to FIG. 4A, FIG. 4B, and FIG. 4C. FIG. 4A, FIG. 4B and FIG. 4C are schematic diagrams of a second embodiment of a pad circuit 30 according to the present invention. In this embodiment, the PMOS transistor P1 is replaced with a cascode circuit 331 or 332 to prevent the leakage issue when the voltages of the first power/ground terminal VDD and the pad 21 increase at the same time. In addition, a diode D1 can be used to prevent the leakage issue. In comparison with the first embodiment, the cascode circuits 331 and 332 further include a PMOS transistor P5. As shown in FIG. 4A, the gate of the PMOS transistor P5 is coupled to the gate of the PMOS transistor P1. The source of the PMOS transistor P5 is coupled to the pad 21. The drain of the PMOS transistor P5 is coupled to the source of the PMOS transistor P1. As shown in FIG. 4B, the gate of the PMOS transistor P5 is coupled to the source of the PMOS transistor P1. The source of the PMOS transistor P5 is coupled to the pad 21. The drain of the PMOS transistor P5 is coupled to the source of the PMOS transistor P1. As shown in FIG. 4C, the diode D1 is coupled between the source of the PMOS transistor P1 and the pad 21.

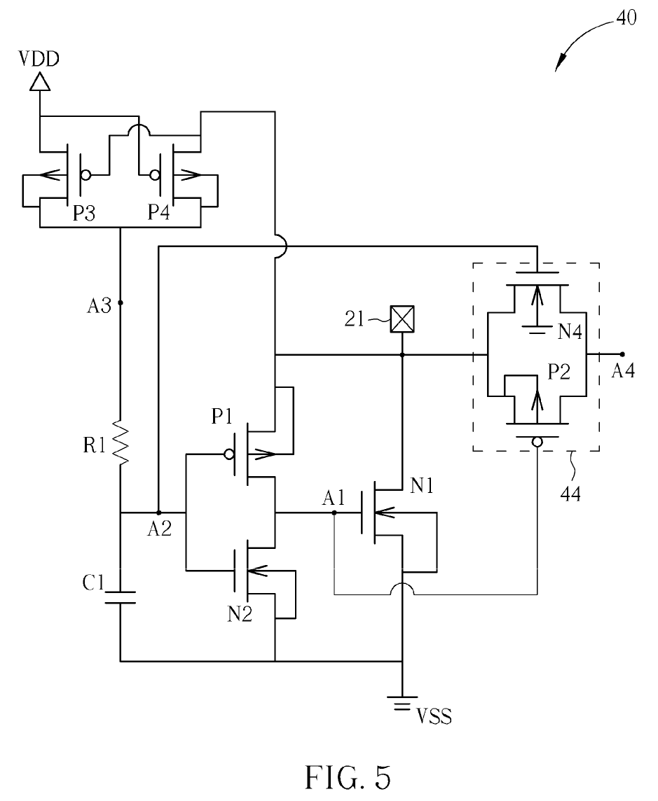

Please refer to FIG.5. FIG. 5 is a schematic diagram of a third embodiment of a pad circuit 40 according to the present invention. In this embodiment, an ESD detection/avoiding circuit 44 uses a transmission gate to improve the electricity. In comparison with the first embodiment, the ESD detection/avoiding circuit 44 further includes an NMOS transistor N4. The gate of the NMOS transistor N4 is coupled to the node A2. The source of the NMOS transistor N4 is coupled to the pad 21. The drain of the NMOS transistor N4 is coupled to the node A4.

In conclusion, the pad circuit according to the present invention includes a pad, a gate driving circuit, a voltage selection circuit, and an ESD detection/avoiding circuit. The gate driving circuit is used to discharge the ESD induced current. The ESD detection/avoiding circuit is used to isolate the ESD induced voltage. The voltage selection circuit selects a higher voltage from a power/ground terminal and the pad and outputs it to the gate driving circuit, so that the pad circuit can be used for the programming and I/O operations.

Those skilled in the art will readily observe that numerous modifications and alterations of the device and method may be made while retaining the teachings of the invention.

What is claimed is:

1. A pad circuit for the programming and I/O operations, comprising:
a pad;
a gate driving circuit, being coupled between the pad and a first power/ground terminal, for discharging an ESD induced current;
a voltage selection circuit, being coupled to the pad and a second power/ground terminal, for outputting a voltage of the pad or a voltage of the second power/ground terminal to the gate driving circuit; and
an ESD detection/avoiding circuit, being coupled to the pad, for isolating an ESD induced voltage.

2. The pad circuit of claim 1, wherein the gate driving circuit comprises:
an first NMOS transistor having a gate, a source coupled to the first power/ground terminal, and a drain coupled to the pad.
a first PMOS transistor having a gate, a source coupled to the pad, and a drain coupled to the gate of the first NMOS transistor;
an second NMOS transistor having a gate coupled to the gate of the first PMOS transistor, a source coupled to the first power/ground terminal, and a drain coupled to the gate of the first NMOS transistor;
a resistor having a first end coupled to the voltage selection circuit, and a second end coupled to the gate of the first PMOS transistor; and
a capacitor having a first end coupled to the second end of the resistor, and a second end coupled to the first power/ground terminal.

3. The pad circuit of claim 2, wherein the gate driving circuit further comprises:
a second PMOS transistor having a gate coupled to the gate of the first PMOS transistor, a source coupled to the pad, and a drain coupled to the source of the first PMOS transistor.

4. The pad circuit of claim 2, wherein the gate driving circuit further comprises:
a second PMOS transistor having a gate coupled to the source of the first PMOS transistor, a source coupled to the pad, and a drain coupled to the source of the first PMOS transistor.

5. The pad circuit of claim 2, wherein the gate driving circuit further comprises:
a diode having a first end coupled to the source of the first PMOS transistor, and a second end coupled to the pad.

6. The pad circuit of claim 1, wherein the voltage selection circuit comprises:
a first PMOS transistor having a gate coupled to the second power/ground terminal, a source coupled to the pad, and a drain coupled to the gate driving circuit; and
a second PMOS transistor having a gate coupled to the pad, a source coupled to the second power/ground terminal, and a drain coupled to the gate driving circuit.

7. The pad circuit of claim 1, wherein the ESD detection/avoiding circuit comprises:
a PMOS transistor having a gate coupled to the gate driving circuit, a source coupled to the pad, and a drain coupled to a programming node.

8. The pad circuit of claim 1, wherein the ESD detection/avoiding circuit comprises:
a PMOS transistor having a gate coupled to the gate driving circuit, a source coupled to the pad, and a drain coupled to a programming node; and
a NMOS transistor having a gate coupled to the gate driving circuit, a source coupled to the programming node, and a drain coupled to the pad.
